(19) United States
(12) Patent Application Publication
(10) Pub. No.: US 2015/0102382 A1
(43) Pub. Date: Apr. 16, 2015

(54) SEMICONDUCTOR LIGHT EMITTING DEVICE AND METHOD FOR MANUFACTURING THE SAME

(71) Applicant: Kabushiki Kaisha Toshiba, Tokyo (JP)

(72) Inventor: Takeyuki Suzuki, Ishikawa-ken (JP)

(73) Assignee: Kabushiki Kaisha Toshiba, Tokyo (JP)

(21) Appl. No.: 14/202,109

(22) Filed: Mar. 10, 2014

(30) Foreign Application Priority Data
Oct. 15, 2013 (JP) 2013-214800

(51) Int. Cl. H01L 33/38; H01L 33/62

(52) U.S. Cl. CPC H01L 33/38; H01L 33/62
USPC 257/99; 438/26

(57) ABSTRACT

According to one embodiment, a semiconductor light emitting device includes a light emitting unit, a first metal layer, a second metal layer, and an intermediate layer. The light emitting unit includes a semiconductor light emitting layer. The first metal layer includes a first metal. The second metal layer is provided between the first metal layer and the light emitting unit and includes the first metal. The intermediate layer is provided between the first metal layer and the second metal layer and includes an intermetallic compound including a second metal.

### CROSS-REFERENCE TO RELATED APPLICATIONS

This application is based upon and claims the benefit of priority from Japanese Patent Application No. 2013-214800, filed on Oct. 15, 2013; the entire contents of which are incorporated herein by reference.

### FIELD

Embodiments described herein relate generally to a semiconductor light emitting device and a method for manufacturing the same.

### BACKGROUND

There are semiconductor light emitting devices such as thin-film LEDs (Light Emitting Diodes), etc., in which, for example, a semiconductor layer including a light emitting layer is bonded to, for example, a copper (Cu) substrate. It is desirable to increase the reliability of such semiconductor light emitting devices.

### BRIEF DESCRIPTION OF THE DRAWINGS

FIG. 1 is a schematic cross-sectional view showing a semiconductor light emitting device according to a first embodiment;

FIG. 2A to FIG. 2C are schematic cross-sectional views showing a method for manufacturing the semiconductor light emitting device according to the first embodiment;

FIG. 3A to FIG. 3F are schematic cross-sectional views showing a method for manufacturing the semiconductor light emitting device according to the first embodiment;

FIG. 4 is a schematic cross-sectional view showing a semiconductor light emitting device according to a second embodiment;

FIG. 5A to FIG. 5C are schematic cross-sectional views showing a method for manufacturing the semiconductor light emitting device according to the second embodiment; and

FIG. 6A and FIG. 6B are schematic cross-sectional views showing a method for manufacturing the semiconductor light emitting device according to the second embodiment.

### DETAILED DESCRIPTION

According to one embodiment, a semiconductor light emitting device includes a light emitting unit, a first metal layer, a second metal layer, and an intermediate layer. The light emitting unit includes a semiconductor light emitting layer. The first metal layer includes a first metal. The second metal layer is provided between the first metal layer and the light emitting unit. The second metal layer includes the first metal. The intermediate layer is provided between the first metal layer and the second metal layer. The intermediate layer includes an intermetallic compound including a second metal.

According to one embodiment, a semiconductor light emitting device includes a light emitting unit, a first metal layer, a second metal layer, and an intermediate layer. The light emitting unit includes a semiconductor light emitting layer. The first metal layer includes a first metal. The second metal layer is provided between the first metal layer and the light emitting unit. The second metal layer includes the first metal. The intermediate layer is provided between the first metal layer and the second metal layer. A Young's modulus of the intermediate layer is higher than a Young's modulus of the first metal layer and higher than a Young's modulus of the second metal layer.

According to one embodiment, a method is disclosed for manufacturing a semiconductor light emitting device. The device includes a light emitting unit, a first metal layer, a second metal layer, and an intermediate layer. The light emitting unit includes a semiconductor light emitting layer. The first metal layer includes a first metal. The second metal layer is provided between the first metal layer and the light emitting unit. The second metal layer includes the first metal. The intermediate layer is provided between the first metal layer and the second metal layer. The intermediate layer includes an intermetallic compound including a second metal. The method can include preparing a first patterning body including a growth substrate, the light emitting unit, a first metal film, and a first bonding metal film, the light emitting unit being provided on the growth substrate, the first metal film being provided on the light emitting unit to become the first metal layer, the first bonding metal film being provided on the first metal film and including the second metal. The method can include preparing a second patterning body including a support substrate, a second metal film, and a second bonding metal film, the second metal film being provided on the support substrate to become the second metal layer, the second bonding metal film being provided on the second metal film and including the second metal. In addition, the method can include forming the intermediate layer from a portion of the first metal film, a portion of the second metal film, at least a portion of the first bonding metal film, and at least a portion of the second bonding metal film by bonding the first bonding metal film with the second bonding metal film.

Various embodiments will be described hereinafter with reference to the accompanying drawings.

The drawings are schematic or conceptual; and the relationships between the thicknesses and widths of portions, the proportions of sizes between portions, etc., are not necessarily the same as the actual values thereof. Further, the dimensions and/or the proportions may be illustrated differently between the drawings, even for identical portions.

In the drawings and the specification of the application, components similar to those described in regard to a drawing thereinabove are marked with like reference numerals, and a detailed description is omitted as appropriate.

### First Embodiment

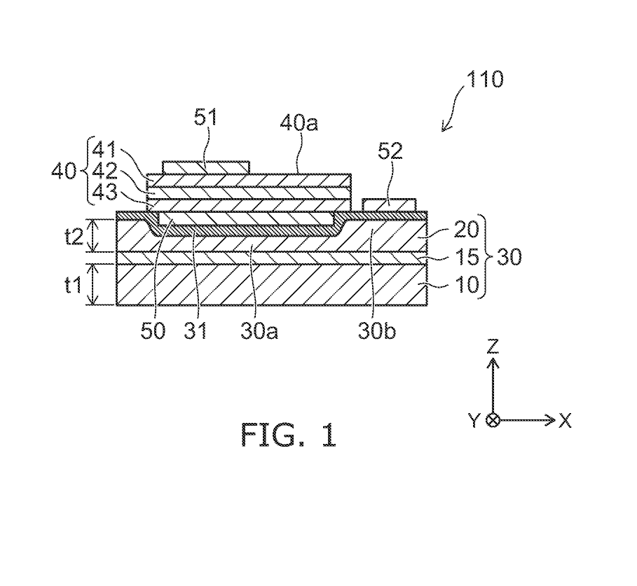

FIG. 1 is a schematic cross-sectional view illustrating a semiconductor light emitting device according to a first embodiment.

As shown in FIG. 1, the semiconductor light emitting device 110 includes a light emitting unit 40 and a stacked unit 30. The stacked unit 30 supports, for example, the light emitting unit 40. The stacked unit 30 includes a first metal layer 10, a second metal layer 20, and an intermediate layer 15.

The second metal layer 20 is provided between the first metal layer 10 and the light emitting unit 40. The intermediate layer 15 is provided between the first metal layer 10 and the second metal layer 20.

The semiconductor light emitting device 110 is, for example, a light emitting diode (LED) that includes a GaN-based nitride semiconductor. The semiconductor light emitting device 110 has, for example, a thin-film structure. For example, an n-type semiconductor layer 41 (e.g., an n-type GaN layer), a light emitting layer 42 (a semiconductor light emitting layer), and a p-type semiconductor layer 43 (e.g., a p-type GaN layer) are provided in the light emitting unit 40. In the example, the p-type semiconductor layer 43 is disposed between the n-type semiconductor layer 41 and the stacked unit 30. The light emitting layer 42 is disposed between the n-type semiconductor layer 41 and the p-type semiconductor layer 43. The light emitting layer 42 includes a semiconductor layer of a nitride semiconductor, etc. The light emitting layer 42 has, for example, a multiple quantum well structure.

A direction from the first metal layer 10 toward the second metal layer 20 is taken as a Z-axis direction. One direction perpendicular to the Z-axis direction is taken as an X-axis direction. One direction perpendicular to the Z-axis direction and perpendicular to the X-axis direction is taken as a Y-axis direction.

For example, a first portion 30a and a second portion 30b are provided in the stacked unit 30. The first portion 30a is the region overlapping the light emitting unit 40 when projected onto the X-Y plane. The second portion 30b is the region not overlapping the light emitting unit 40 when projected onto the X-Y plane.

In the example, a reflecting electrode 50 is provided between the light emitting unit 40 and the first portion 30a. The reflecting electrode 50 includes, for example, silver (Ag). The reflecting electrode 50 reflects the light emitted from the light emitting layer 42 toward the direction of a light emitting surface 40a.

For example, a seed layer 31 is provided on the stacked unit 30. The second metal layer 20 is disposed between the seed layer 31 and the intermediate layer 15. An n-electrode 51 is provided on the n-type semiconductor layer 41. In the example, a p-electrode 52 is provided on the seed layer 31. The p-electrode 52 may be provided on the lower surface of the stacked unit 30. For example, the p-electrode 52 is electrically connected to the reflecting electrode 50 via the seed layer 31.

The first metal layer 10 includes a first metal. The first metal includes, for example, at least one selected from copper (Cu) and gold (Au). The first metal layer 10 is, for example, a Cu layer. A thickness t1 of the first metal layer 10 is, for example, not less than 10 μm (micrometers) and not more than 150 μm. It is favorable to be not less than 10 μm and not more than 70 μm.

The second metal layer 20 includes the first metal recited above. The second metal layer 20 is, for example, a Cu layer. A thickness t2 of the second metal layer 20 is, for example, not less than 10 μm and not more than 150 μm. It is favorable to be not less than 10 μm and not more than 70 μm. The thickness t2 is, for example, substantially the same as the thickness t1.

The Young's modulus of the intermediate layer 15 is higher than the Young's modulus of the first metal layer 10 and higher than the Young's modulus of the second metal layer 20. In other words, the intermediate layer 15 that has a high Young's modulus is provided in a portion of the stacked unit 30 (e.g., a thickness-direction central portion). Thereby, the warp of the stacked unit 30 can be suppressed.

The intermediate layer 15 includes, for example, a compound including the first metal (e.g., Cu) and a second metal. The second metal includes, for example, at least one selected from tin (Sn), indium (In), and bismuth (Bi).

The intermediate layer 15 includes, for example, an intermetallic compound including the second metal. The intermediate layer 15 includes, for example, an intermetallic compound of the first metal and the second metal. The thickness of the intermediate layer 15 is, for example, not less than 5 μm and not more than 60 μm.

The thickness of the stacked unit 30 is, for example, the total of the thickness t1 of the first metal layer 10, the thickness t2 of the second metal layer 20, and the thickness of the intermediate layer 15. The thickness of the stacked unit 30 is, for example, not less than 50 μm and not more than 300 μm. Thereby, good strength as a semiconductor light emitting device is obtained. Also, good dicing performance, etc., is obtained.

On the other hand, the total of the thickness of the light emitting unit 40 and the thickness of the n-electrode 51 is, for example, about 5 μm. The thickness of the light emitting unit 40 is thinner than the thickness of the stacked unit 30. The thickness of the light emitting unit 40 is not less than about 0.005 times and not more than about 0.1 times the thickness of the stacked unit 30.

An example of a method for manufacturing the semiconductor light emitting device 110 according to the first embodiment will now be described.

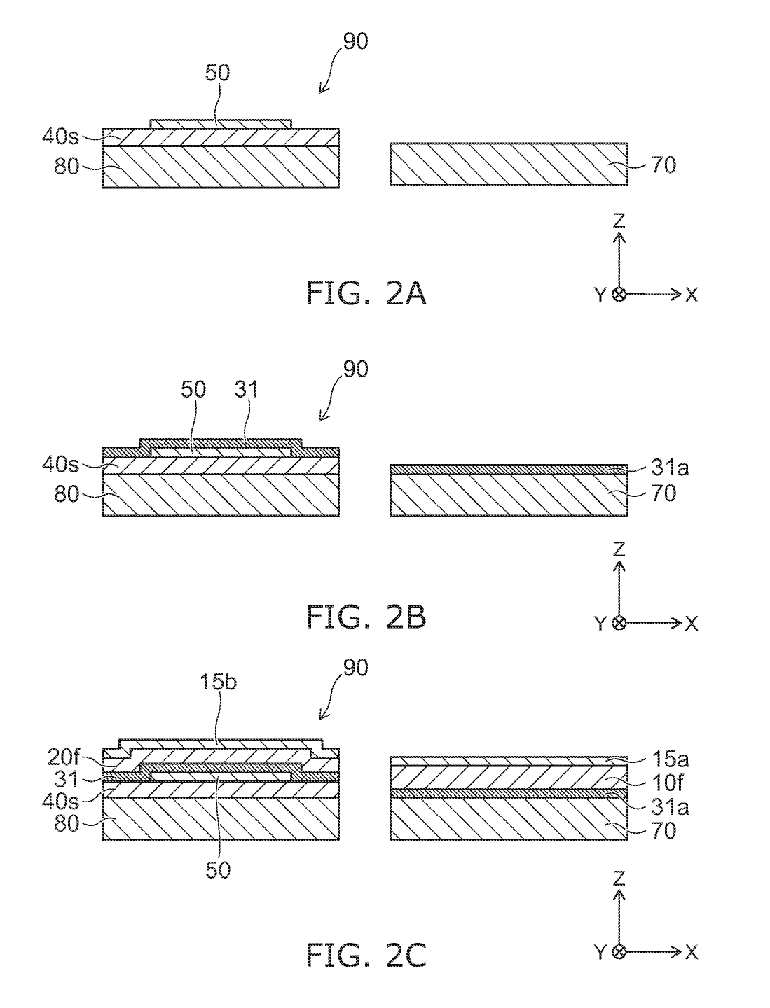

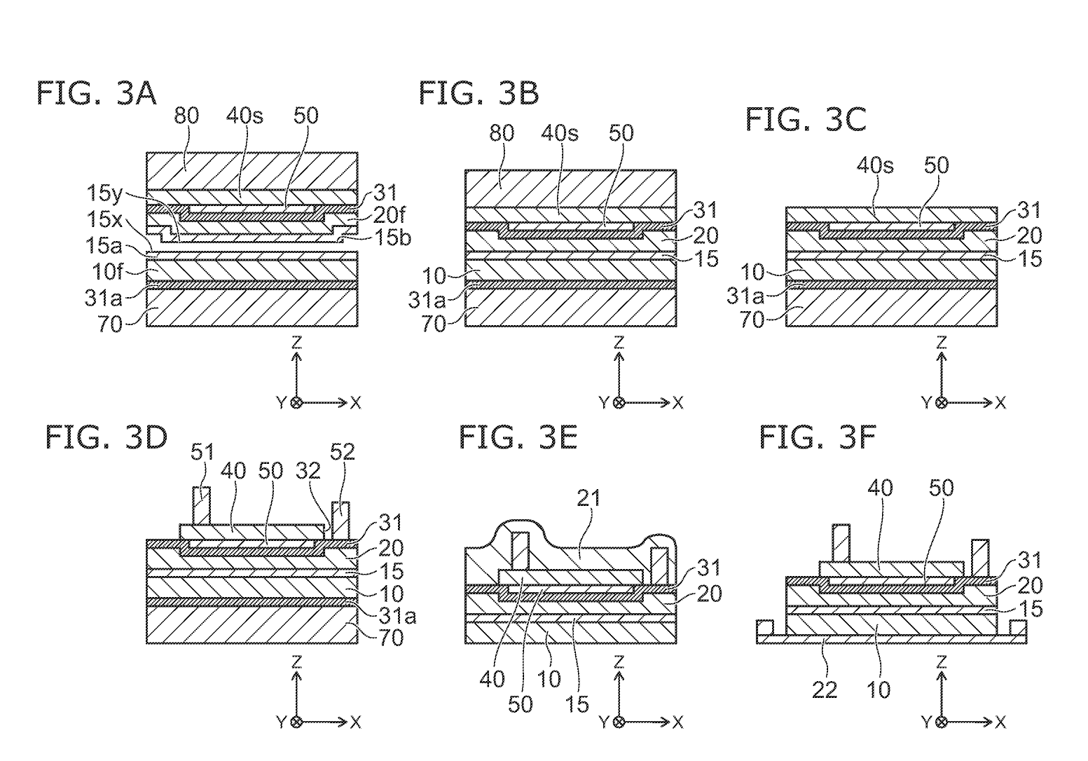

FIG. 2A to FIG. 2C and FIG. 3A to FIG. 3F are schematic cross-sectional views illustrating the method for manufacturing the semiconductor light emitting device according to the first embodiment.

As shown in FIG. 2A, a wafer 90 and a support substrate 70 are prepared. A growth substrate 80 and a semiconductor stacked body 40s that is used to form the light emitting unit 40 are provided in the wafer 90. The semiconductor stacked body 40s is provided on the growth substrate 80. The semiconductor stacked body 40s is formed on the growth substrate 80 by, for example, epitaxial growth. The n-type semiconductor layer 41, the light emitting layer 42, and the p-type semiconductor layer 43 are formed in this order in the semiconductor stacked body 40s. For example, the semiconductor stacked body 40s is formed by MOCVD (Metal Organic Vapor Deposition), MBE (Molecular Beam Epitaxy), etc.

The growth substrate 80 includes, for example, a sapphire substrate, a silicon (Si) substrate, or a silicon carbide (SiC) substrate. The growth substrate 80 of the embodiment is arbitrary.

The reflecting electrode 50 is formed on the semiconductor stacked body 40s. The reflecting electrode 50 is formed by, for example, vacuum vapor deposition.

As shown in FIG. 2B, the seed layer 31 is formed on the wafer 90. The seed layer 31 includes, for example, a titanium (Ti) layer and a Cu layer. For example, the Ti layer is formed on the wafer 90 by sputtering. The Cu layer is formed by sputtering on the Ti layer. The thickness of the Ti layer is, for example, about 200 nanometers (nm) (e.g., not less than 150 nm and not more than 300 nm). The thickness of the Cu layer is, for example, 600 nm (e.g., not less than 300 nm and not more than 900 nm).

A seed layer 31a is formed on the support substrate 70. The seed layer 31a may be formed simultaneously with the seed layer 31. The seed layer 31a may have a configuration (materials, thickness, stacking configuration, etc.) that is similar to that of the seed layer 31.

As shown in FIG. 2C, a second metal film 20f is formed on the seed layer 31. The second metal film 20f is used to form the second metal layer 20. For example, the second metal film 20f is formed by electroplating. In the example, the second metal film 20f (the second metal layer 20) includes Cu. Subsequently, a second bonding metal film 15b is formed on the second metal film 20f. The second bonding metal film 15b includes, for example, the second metal. For example, the second bonding metal film 15b is formed by electroplating. The second bonding metal film 15b includes, for example, a metal having a low melting point such as Sn, In, Bi, etc.

A first metal film 10f is formed on the seed layer 31a. The first metal film 10f is used to form the first metal layer 10. For example, the first metal film 10f is formed by electroplating. In the example, the first metal film 10f (the first metal layer 10) includes Cu. The first metal film 10f may be formed simultaneously with the second metal film 20f. The first metal film 10f may have a configuration (materials, thickness, stacking configuration, etc.) that is similar to that of the second metal film 20f.

A first bonding metal film 15a is formed on the first metal film 10f. For example, the first bonding metal film 15a is formed by electroplating. The first bonding metal film 15a includes the second metal. The first bonding metal film 15a includes, for example, a metal having a low melting point such as Sn, In, Bi, etc. The first bonding metal film 15a may be formed simultaneously with the second bonding metal film 15b. The second bonding metal film 15b may have a configuration (materials, thickness, stacking configuration, etc.) that is similar to that of the first bonding metal film 15a.

It is desirable for the thickness of the first bonding metal film 15a and the thickness of the second bonding metal film 15b to be 1.5 μm or more. Thereby, for example, the bonding defects of the process described below do not occur easily.

As shown in FIG. 3A, the support substrate 70 and the wafer 90 are caused to overlap each other. In other words, a bonding surface 15x of the first bonding metal film 15a is caused to contact a bonding surface 15y of the second bonding metal film 15b. The bonding surface 15x and the bonding surface 15y are brought into contact; and the temperature is increased while applying pressure. The state of being under pressure and at the elevated temperature is maintained for a constant amount of time.

Thereby, as shown in FIG. 3B, the first bonding metal film 15a and the second bonding metal film 15b are bonded. The intermediate layer 15 is formed in the bonding process. For example, the intermediate layer 15 is formed from a portion of the first metal film 10f, a portion of the second metal film 20f, at least a portion of the first bonding metal film 15a, and at least a portion of the second bonding metal film 15b.

For example, a compound that has a Young's modulus (a rigidity) that is higher than that of Cu (the first metal) is formed in the bonding process. The intermediate layer 15 includes a compound including the Cu included in the first metal layer 10 and the metal (the second metal) included in the first bonding metal film 15a. The intermediate layer 15 includes, for example, an intermetallic compound of Cu and the metal included in the first bonding metal film 15a. The intermetallic compound is, for example, Cu₆Sn₅, Cu₃Sn, etc. The intermetallic compound is confirmed by, for example, structure analysis using an electron beam, etc.

As shown in FIG. 3C, the growth substrate 80 is separated from the light emitting unit 40. For example, in the case where the growth substrate 80 includes a sapphire substrate, the growth substrate 80 is peeled (e.g., laser lift-off is performed) by irradiating laser light onto the semiconductor stacked body 40s via the growth substrate 80. For example, in the case where the growth substrate 80 includes a Si substrate, the Si substrate is polished by spin etching. Thereby, the light emitting unit 40 can remain on the support substrate 70 side; and the growth substrate 80 can be removed. Polishing and dry etching of the Si substrate may be performed to remove the growth substrate 80.

For example, in the case where the growth substrate 80 includes a SiC substrate, polishing and dry etching of the SiC substrate is performed. Thereby, the growth substrate 80 can be removed.

As shown in FIG. 3D, a mesa portion 32 is formed by etching the light emitting unit 40. Thereby, the seed layer 31 is exposed. For example, the p-electrode 52 is formed on the seed layer 31. The n-electrode 51 is formed on the light emitting unit 40 (in the example, on the n-type semiconductor layer 41). The n-electrode 51 is formed by, for example, vacuum vapor deposition. For example, the n-electrode 51 has an Al/Ti/Au stacked structure.

As shown in FIG. 3E, a protective tape 21 is adhered to the upper surface of the light emitting unit 40. The first metal layer 10 remains; and the support substrate 70 is removed. For example, the support substrate 70 is removed by polishing.

As shown in FIG. 3F, a tape 22 for dicing is adhered to the surface on the second metal layer 20 side; and the protective tape 21 is peeled. Subsequently, dicing is performed; and the semiconductor light emitting device 110 is completed.

By a simple bonding method such as that recited above, the intermetallic compound can be made easily in the middle of the stacked unit 30.

In the bonding process of the first bonding metal film 15a with the second bonding metal film 15b as recited above, the intermetallic compound (the intermediate layer 15) that has, for example, a Young's modulus that is higher than that of Cu (the first metal layer 10 and the second metal layer 20) is formed in the stacked unit 30. Thereby, compared to the case where intermediate layer 15 is not provided in the stacked unit 30, the Young's modulus of the stacked unit 30 increases; and the rigidity (the resistance to warp) of the stacked unit 30 is higher. Thereby, warp of the stacked unit 30 is suppressed. As described above, the thickness of the light emitting unit 40 is extremely thin compared to the thickness of the stacked unit 30. By the warp of the stacked unit 30 being suppressed, the warp of the entire semiconductor light emitting device 110 also can be suppressed.

The formation of the light emitting unit 40 on the growth substrate 80 is performed by epitaxial growth at a high temperature. After the formation of the light emitting unit 40, warp occurs easily in the growth substrate 80 and the light emitting unit 40 due to the difference between the coefficients of thermal expansion of the growth substrate 80 and the light emitting unit 40 when returning to room temperature. The stacked unit 30 is provided for such a growth substrate 80 and such a light emitting unit 40.

In the embodiment, the Young's modulus is increased in the stacked unit 30. Thereby, even in the case where the warp occurs in the growth substrate 80 and the light emitting unit 40, the warp is suppressed by the stacked unit 30 having the increased Young's modulus.

For example, there is a reference example in which a support substrate of Si is bonded to the growth substrate 80 and the light emitting unit 40. The support substrate of Si of the reference example corresponds to the stacked unit 30 of the embodiment. The Young's modulus of Si is higher than the Young's modulus of a metal such as Cu, etc. Therefore, it is difficult for the warp of the reference example using the support substrate of Si to become problematic. However, the thermal conductivity of Si is lower than that of a metal such as Cu, etc. Therefore, the heat dissipation of the reference example is poor; and the temperature of the semiconductor layer easily increases excessively during the use of the semiconductor light emitting device. Therefore, there is room for improvement of the reliability of the reference example.

Conversely, in the semiconductor light emitting device 110 according to the embodiment, a metal having high thermal conductivity is used as the stacked unit 30. Thereby, good heat dissipation is obtained; and high reliability is obtained.

On the other hand, a reference example also may be considered in which a metal is used as the stacked unit 30 and the intermediate layer 15 is not provided in the stacked unit 30. However, in such a case, the Young's modulus of the stacked unit 30 is lower than that of the case where the intermediate layer 15 is provided. Therefore, the suppression of the warp in the reference example is insufficient.

In the case where the warp is not suppressed sufficiently, problems occur easily in the transfer by apparatuses in the manufacturing processes; and efficient manufacturing becomes difficult. For example, when a large warp occurs in the stacked unit 30, the stacked unit 30 may undesirably peel from the tape 22 when adhering the tape 22 during the dicing. Further, in the case where stress caused by the warp remains in the completed semiconductor light emitting device, cracks in the semiconductor layer, peeling of the electrodes, etc., occur easily. In other words, there are cases where the reliability of the semiconductor light emitting device decreases due to the stress caused by the warp.

Conversely, in the embodiment, the rigidity of the stacked unit 30 is increased by providing the intermediate layer 15 having the high Young's modulus in the stacked unit 30. Thereby, the warp is suppressed. Efficient manufacturing becomes possible because the warp can be suppressed; and the reliability of the semiconductor light emitting device can be increased by the stress being relaxed. Simultaneously, by using the stacked unit 30 including the metal, good heat dissipation is obtained; and high reliability is obtained.

An example of a ratio Ra of the thickness of the intermediate layer 15 to the thickness of the stacked unit 30 will now be described. The ratio Ra is the thickness of the intermediate layer 15 divided by the thickness of the stacked unit 30. For example, it is considered that the thermal conductivity of the entire stacked unit 30 depends on the ratio Ra.

For example, the thermal conductivity of Cu is about 380 W/mK. On the other hand, the thermal conductivity of Sn is about 70 W/mK. Accordingly, in the case where the ratio Ra is small (in the case where the intermediate layer 15 is thin compared to the stacked unit 30), high thermal conductivity is obtained. For example, in the case where the ratio Ra is less than 0.85, the thermal conductivity of the stacked unit 30 can be high, that is, about 140 W/mK or more. For example, in the case where the ratio Ra is less than 0.5, the thermal conductivity of the stacked unit 30 can be high, that is, about 200 W/mK or more. In the embodiment, for example, the thickness of the intermediate layer 15 is set to be not more than 0.85 times the thickness of the stacked unit 30. A higher thermal conductivity is obtained by setting the thickness of the intermediate layer 15 to be not more than 0.5 times the thickness of the stacked unit 30.

It is considered that the Young's modulus of the entire stacked unit 30 depends on the ratio Ra.

The Young's modulus is about 100 GPa for metals. For example, the Young's modulus is about 200 GPa to 300 GPa for ceramics. For example, the Young's modulus of an intermetallic compound (Ra=1) of Cu and Sn is, for example, about 150 GPa. The Young's modulus of Cu (Ra=0) is about 110 GPa. By employing the structure according to the embodiment, the Young's modulus of the stacked unit 30 can be set to be, for example, about 25% to 30% higher. Thereby, the warp of the stacked unit 30 is suppressed. The reliability of the semiconductor light emitting device increases.

For example, the thickness t1 of the first metal layer 10 is set to be about the same as the thickness t2 of the second metal layer 20. For example, the intermediate layer 15 may be provided at the position of the central vicinity of the stacked unit 30 in the thickness direction of the stacked unit 30. A layer having a high Young's modulus is provided at the central vicinity of the stacked unit. Thereby, for example, the warp of the stacked unit 30 is suppressed further. There are cases where the first metal layer 10 and the second metal layer 20 themselves have internal stress due to the formation method. In such a case, for example, the internal stress can be suppressed (e.g., canceled) by setting the thickness t1 of the first metal layer 10 and the thickness t2 of the second metal layer 20 to be equivalent. For example, the thickness t1 of the first metal layer 10 is not less than 0.8 times and not more than 1.2 times the thickness t2 of the second metal layer 20.

According to the embodiment, a semiconductor light emitting device and a method for manufacturing the semiconductor light emitting device having high reliability are provided by inserting the intermediate layer 15 having the high Young's modulus into the stacked unit 30 including the metal.

For example, in the case where Cu is included in the first metal layer 10 and the second metal layer 20 and Sn is included in the first bonding metal film 15a and the second bonding metal film 15b, bonding defects may occur between the first bonding metal film 15a and the second bonding metal film 15b.

According to investigations of the inventor of the application, it was found that, for example, the bonding defects occur easily in the case where the reaction between the Cu of the first metal layer 10 and the Sn of the first bonding metal film 15a is fast. For example, there are cases where the reaction between the Cu of the first metal layer 10 and the Sn of the first bonding metal film 15a proceeds faster than the bond formation of the bonding surface 15x and the bonding surface 15y. In such a case, the bonding defects occur easily. In other words, the bonding of the bonding surface 15x and the bonding surface 15y substantially does not occur after, for example, the metal compound is produced by the reaction between the Cu of the first metal layer 10 and the Sn of the first bonding metal film 15a.

The speed of the bond formation of the metals depends on, for example, the temperature, pressure, etc., of the bonding. It was discovered that the occurrence of the bonding defects can be suppressed by setting the temperature, pressure, etc., of the bonding. In other words, the bond formation of the bonding surface 15x and the bonding surface 15y proceeds faster than the reaction between the first metal layer 10 and the first bonding metal film 15a. Thereby, the occurrence of the bonding defects can be suppressed.

It is desirable for the temperature of the bonding to be higher than the melting point of the metal included in the first bonding metal film 15a and the second bonding metal film 15b by not less than 20° C. In the case where Sn is included in the first bonding metal film 15a and the second bonding metal film 15b, it is desirable for the temperature of the bonding to be not less than 250° C. and not more than 350° C. It is desirable for the temperature of the bonding to increase at a sufficient speed. For example, it is desirable for the temperature to increase at about 60° C./minute. It is desirable for the thickness of the first bonding metal film 15a to be 1.5 μm or more. Thereby, for example, it is possible for Sn that has not reacted with Cu to remain at the bonding surface 15x and the bonding surface 15y. Thereby, the reaction between the Cu and the Sn at the bonding surface 15x and the bonding surface 15y can be implemented sufficiently.

In the case where Sn is included in the first bonding metal film 15a and the second bonding metal film 15b and the thickness of the first bonding metal film 15a and the thickness of the second bonding metal film 15b are 1.5 μm, it is desirable for the hold time in the state of being at the elevated temperature and under pressure to be, for example, about 15 minutes. It is desirable for the pressure applied in the bonding to be 0.5 MPa or more. Thereby, the occurrence of the bonding defects can be suppressed.

By using a metal having a low melting point such as Sn, etc., as the second metal, the bonding can be performed at a relatively low temperature. For example, the time necessary for the heating and cooling of the bonding is shorter. Thereby, for example, the reaction of the Cu and the Sn at the bonding surface 15x and the bonding surface 15y stabilizes; and the bonding defects can be suppressed.

In the case where the temperature of the bonding is low, for example, the difference between the thermal expansion of the support substrate 70 and the thermal expansion of the first metal film 10f in the bonding can be reduced. Thereby, for example, the stress that is applied to the stacked unit 30 can be reduced; and the warp of the stacked unit 30 can be suppressed.

In the case where the temperature of the bonding is too high, for example, there are cases where the p-electrode 52 is altered. For example, the resistance value of the p-electrode 52 changes. Thereby, the characteristics of the semiconductor light emitting device may undesirably fluctuate. By performing the bonding at a low temperature by using a metal having a low melting point as the second metal, for example, the fluctuation of the characteristics can be suppressed; and a semiconductor light emitting device having stable characteristics can be made.

According to the manufacturing method of the embodiment, the occurrence of the bonding defects can be suppressed; and the intermediate layer 15 can be formed inside the stacked unit 30 including the metal. Thereby, a semiconductor light emitting device having improved heat dissipation, suppressed warp, and high reliability can be provided.

### Second Embodiment

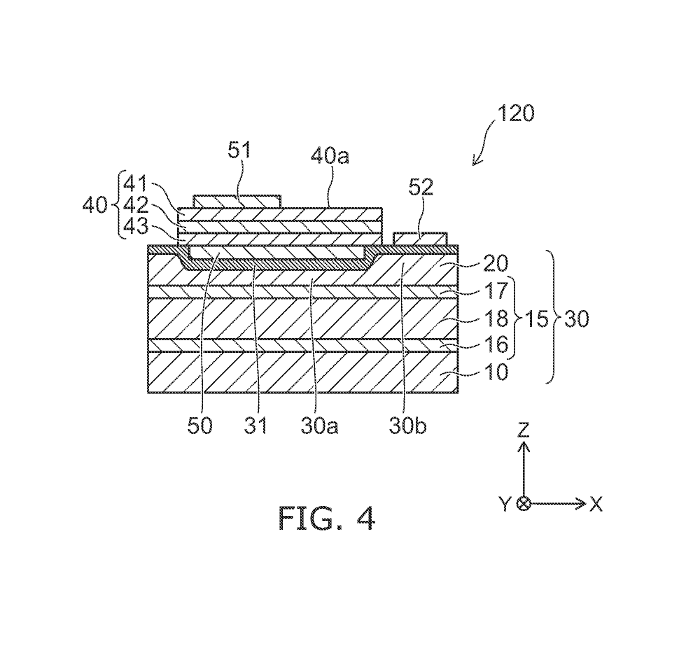

FIG. 4 is a schematic cross-sectional view illustrating a semiconductor light emitting device according to a second embodiment.

As shown in FIG. 4, the light emitting unit 40 and the stacked unit 30 are provided in the semiconductor light emitting device 120. In the example as well, the seed layer 31, the reflecting electrode 50, the n-electrode 51, and the p-electrode 52 are provided. The stacked unit 30 includes the first metal layer 10, the second metal layer 20, and the intermediate layer 15. The configuration described in regard to the semiconductor light emitting device 110 is applicable to the light emitting unit 40, the seed layer 31, the reflecting electrode 50, the n-electrode 51, the p-electrode 52, the first metal layer 10, and the second metal layer 20.

In the semiconductor light emitting device 120, the intermediate layer 15 includes a first intermediate metal layer 16, a second intermediate metal layer 17, and a third intermediate metal layer 18.

The second intermediate metal layer 17 is provided between the first intermediate metal layer 16 and the second metal layer 20. The third intermediate metal layer 18 is provided between the first intermediate metal layer 16 and the second intermediate metal layer 17.

The first intermediate metal layer 16 and the second intermediate metal layer 17 include a third metal. The third metal includes, for example, at least one selected from nickel (Ni), cobalt (Co), molybdenum (Mo), chrome (Cr), vanadium (V), and tantalum (Ta).

The third intermediate metal layer 18 includes, for example, a compound including the second metal and the third metal. The third intermediate metal layer 18 includes, for example, an intermetallic compound of the second metal and the third metal.

In the second embodiment, the thickness of the stacked unit 30 is, for example, not less than 50 μm and not more than 300 μm. The thickness of the first metal layer 10 is, for example, not less than 10 μm and not more than 150 μm. It is favorable to be not less than 10 μm and not more than 100 μm. The thickness of the second metal layer 20 is, for example, not less than 10 μm and not more than 150 μm. It is favorable to be not less than 10 μm and not more than 100 μm.

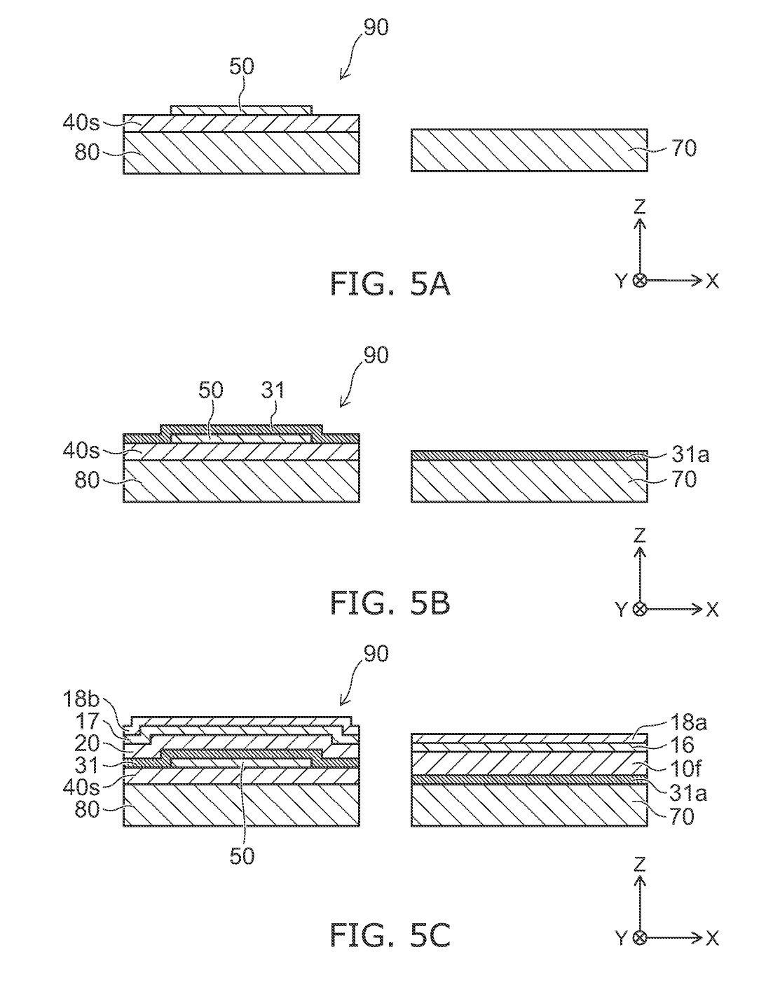

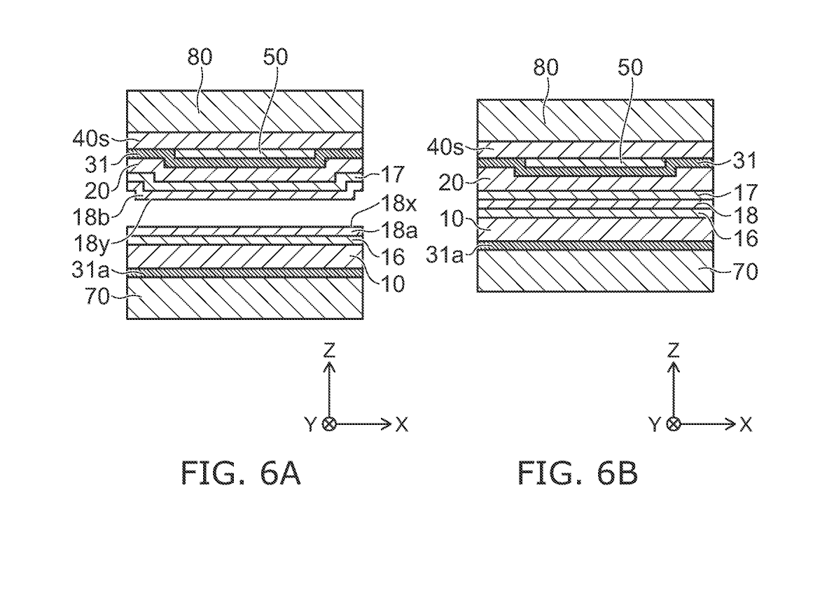

FIG. 5A to FIG. 5C and FIG. 6A and FIG. 6B are schematic cross-sectional views illustrating a method for manufacturing the semiconductor light emitting device according to the second embodiment.

As shown in FIG. 5A, the wafer 90 and the support substrate 70 are prepared. As shown in FIG. 5B, the seed layer 31 is formed on the wafer 90. The seed layer 31a is formed on the support substrate 70.

As shown in FIG. 5C, the second metal layer 20 is provided on the seed layer 31. Subsequently, the second intermediate metal layer 17 is provided on the second metal layer 20. For example, the second intermediate metal layer 17 is formed by electroplating or PVD (Physical Vapor Deposition). The second intermediate metal layer 17 includes, for example, Ni or Co. The first metal layer 10 is provided on the seed layer 31a.

Subsequently, the first intermediate metal layer 16 is provided on the first metal layer 10. For example, the first intermediate metal layer 16 is formed by electroplating or PVD. The first intermediate metal layer 16 includes, for example, Ni or Co.

Subsequently, a third bonding metal film 18a is provided on the first intermediate metal layer 16. For example, the third bonding metal film 18a is formed by electroplating or PVD. The third bonding metal film 18a includes, for example, Sn, In, Bi, etc.

A fourth bonding metal film 18b is provided on the second intermediate metal layer 17. For example, the fourth bonding metal film 18b is formed by electroplating or PVD. The fourth bonding metal film 18b includes, for example, Sn, In, Bi, etc.

As shown in FIG. 6A, the support substrate 70 and the wafer 90 are caused to overlap each other. In other words, a bonding surface 18x of the third bonding metal film 18a is caused to contact a bonding surface 18y of the fourth bonding metal film 18b. The bonding surface 18x and the bonding surface 18y are brought into contact; and the temperature is increased while applying pressure. The state of being under pressure and at the elevated temperature is maintained for a constant amount of time.

Thereby, as shown in FIG. 6B, the third bonding metal film 18a and the fourth bonding metal film 18b are bonded. The third intermediate metal layer 18 is formed in the bonding process. Subsequently, the manufacturing method is similar to the semiconductor light emitting device 110 according to the first embodiment.

The third intermediate metal layer 18 includes, for example, a compound including the metal (the third metal) included in the first intermediate metal layer 16 and the second intermediate metal layer 17 and the metal (the second metal) included in the third bonding metal film 18a and the fourth bonding metal film 18b.

The third intermediate metal layer 18 includes, for example, an intermetallic compound of the metal (the third metal) included in the first intermediate metal layer 16 and the second intermediate metal layer 17 and the metal (the second metal) included in the third bonding metal film 18a and the fourth bonding metal film 18b.

For example, the third intermediate metal layer 18 includes a compound that has a Young's modulus (a rigidity) that is higher than that of Cu. For example, Ni₃Sn₄ or the like is formed in the bonding process. The Young's modulus of the intermediate layer 15 including the third intermediate metal layer 18 is higher than that of Cu. In the semiconductor light emitting device 120, similarly to the semiconductor light emitting device 110, the thickness of the intermediate layer 15 is set to be, for example, not more than 0.85 times the thickness of the stacked unit 30.

It is desirable for the temperature of the bonding to be higher than the melting point of the metal included in the third bonding metal film 18a and the fourth bonding metal film 18b by not less than 20° C. In the case where Sn is included in the third bonding metal film 18a and the fourth bonding metal film 18b, it is desirable for the temperature of the bonding to be 250° C. to 350° C. It is desirable for the thicknesses of the third bonding metal film 18a and the fourth bonding metal film 18b to be 1.0 μm or more. For example, it is desirable for a thickness t18a of the third bonding metal film 18a to be not less than 0.3 times a thickness t16 of the first intermediate metal layer 16. Thereby, for example, the occurrence of the bonding defects can be suppressed.

For example, Sn is included in the third bonding metal film 18a and the fourth bonding metal film 18b; and the thickness of the Sn is set to be 1.0 μm. For example, Ni is included in the first intermediate metal layer 16 and the second intermediate metal layer 17. For example, the temperature of the bonding is set to be 280° C.

In the case where the thickness of the Sn is set to be 1.0 μm, it is desirable for the hold time in the state of being at the elevated temperature and under pressure to be about 3 minutes. In the case where the thickness of the Sn is set to be 3.0 μm, it is desirable for the hold time to be about 60 minutes. Thereby, for example, the occurrence of the bonding defects can be suppressed.

In the embodiment, the intermediate layer 15 having the high Young's modulus is provided in the stacked unit 30. Thereby, the warp of the stacked unit 30 can be suppressed; and the reliability of the semiconductor light emitting device can be increased. By using the stacked unit 30 including the metal, good heat dissipation is obtained; and high reliability is obtained.

According to the embodiment, for example, the intermediate layer 15 having the high Young's modulus is inserted into the stacked unit 30 including the metal. According to the embodiment, for example, the intermediate layer 15 that includes the intermetallic compound is provided. According to the embodiment, a semiconductor light emitting device and a method for manufacturing the semiconductor light emitting device having high reliability are provided.

According to the embodiments, a semiconductor light emitting device and a method for manufacturing the semiconductor light emitting device having high reliability are provided.

Hereinabove, exemplary embodiments of the invention are described with reference to specific examples. However, the invention is not limited to these specific examples. For example, one skilled in the art may similarly practice the invention by appropriately selecting specific configurations of components such as the light emitting unit, the first metal layer, the second metal layer, the intermediate layer, etc., from known art; and such practice is within the scope of the invention to the extent that similar effects are obtained.

Further, any two or more components of the specific examples may be combined within the extent of technical feasibility and are included in the scope of the invention to the extent that the purport of the invention is included.

Moreover, all semiconductor light emitting devices and methods for manufacturing the same practicable by an appropriate design modification by one skilled in the art based on the semiconductor light emitting devices and methods for manufacturing the same described above as embodiments of the invention also are within the scope of the invention to the extent that the spirit of the invention is included.

Various other variations and modifications can be conceived by those skilled in the art within the spirit of the invention, and it is understood that such variations and modifications are also encompassed within the scope of the invention.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the invention.

What is claimed is:

1. A semiconductor light emitting device, comprising:
a light emitting unit including a semiconductor light emitting layer;
a first metal layer including a first metal;
a second metal layer provided between the first metal layer and the light emitting unit, the second metal layer including the first metal; and
an intermediate layer provided between the first metal layer and the second metal layer, the intermediate layer including an intermetallic compound including a second metal.

2. The device according to claim 1, wherein a Young's modulus of the intermediate layer is higher than a Young's modulus of the first metal layer and higher than a Young's modulus of the second metal layer.

3. The device according to claim 1, wherein the intermetallic compound includes an intermetallic compound of the second metal and the first metal.

4. The device according to claim 1, wherein the second metal includes at least one selected from tin, indium, and bismuth.

5. The device according to claim 1, wherein the intermediate layer includes
a first intermediate metal layer including a third metal,
a second intermediate metal layer including the third metal, and
a third intermediate metal layer provided between the first intermediate metal layer and the second intermediate metal layer, the third intermediate metal layer including a compound including the second metal and the third metal.

6. The device according to claim 5, wherein the third metal includes at least one selected from nickel, cobalt, molybdenum, chrome, vanadium, and tantalum.

7. The device according to claim 5, wherein the third intermediate metal layer includes an intermetallic compound of the second metal and the third metal.

8. A semiconductor light emitting device, comprising:
a light emitting unit including a semiconductor light emitting layer;
a first metal layer including a first metal;
a second metal layer provided between the first metal layer and the light emitting unit, the second metal layer including the first metal; and
an intermediate layer provided between the first metal layer and the second metal layer,
a Young's modulus of the intermediate layer being higher than a Young's modulus of the first metal layer and higher than a Young's modulus of the second metal layer.

9. The device according to claim 1, wherein the first metal includes at least one selected from copper and gold.

10. The device according to claim 1, wherein a thickness of the first metal layer is not less than 0.8 times a thickness of the second metal layer and not more than 1.2 times the thickness of the second metal layer.

11. The device according to claim 1, wherein a thickness of the light emitting unit is not more than 0.1 times a total of a thickness of the first metal layer, a thickness of the second metal layer, and a thickness of the intermediate layer.

12. The device according to claim 1, wherein a total of a thickness of the first metal layer, a thickness of the second metal layer, and a thickness of the intermediate layer is not less than 50 micrometers and not more than 300 micrometers.

13. The device according to claim 1, wherein a thickness of the intermediate layer is not more than 0.85 times the total of a thickness of the first metal layer, a thickness of the second metal layer, and a thickness of the intermediate layer.

14. A method for manufacturing a semiconductor light emitting device, the device including a light emitting unit, a first metal layer, a second metal layer, and an intermediate layer, the light emitting unit including a semiconductor light emitting layer, the first metal layer including a first metal, the second metal layer being provided between the first metal layer and the light emitting unit, the second metal layer including the first metal, the intermediate layer being provided between the first metal layer and the second metal layer, the intermediate layer including an intermetallic compound including a second metal, the method comprising:
preparing a first patterning body including a growth substrate, the light emitting unit, a first metal film, and a first bonding metal film, the light emitting unit being provided on the growth substrate, the first metal film being provided on the light emitting unit to become the first metal layer, the first bonding metal film being provided on the first metal film and including the second metal;
preparing a second patterning body including a support substrate, a second metal film, and a second bonding metal film, the second metal film being provided on the support substrate to become the second metal layer, the second bonding metal film being provided on the second metal film and including the second metal; and
forming the intermediate layer from a portion of the first metal film, a portion of the second metal film, at least a portion of the first bonding metal film, and at least a portion of the second bonding metal film by bonding the first bonding metal film with the second bonding metal film.

15. The method according to claim 14, wherein a Young's modulus of the intermediate layer is higher than a Young's modulus of the first metal layer and higher than a Young's modulus of the second metal layer.

16. The method according to claim 14, wherein the intermetallic compound includes an intermetallic compound of the second metal and the first metal.

17. The method according to claim 14, wherein the second metal includes at least one selected from tin, indium, and bismuth.

18. The method according to claim 14, wherein the first metal includes at least one selected from copper and gold.

19. The method according to claim 14, wherein a thickness of the first metal layer is not less than 0.8 times a thickness of the second metal layer and not more than 1.2 times the thickness of the second metal layer.

20. The method according to claim 14, wherein a thickness of the light emitting unit is not more than 0.1 times a total of a thickness of the first metal layer, a thickness of the second metal layer, and a thickness of the intermediate layer.
